(19) United States
(12) Patent Application Publication
(10) Pub. No.: US 2025/0142895 A1
(43) Pub. Date: May 1, 2025

(54) EMBEDDED FLASH MEMORY STRUCTURE AND METHOD OF MANUFACTURING THE SAME

(71) Applicant: UNITED MICROELECTRONICS CORP., Hsin-Chu City (TW)

(72) Inventors: Pei-Lun Jheng, Tainan City (TW); Po-Jui Chiang, Changhua County (TW); Chao-Sheng Cheng, Taichung City (TW); Ming-Jen Chang, Hsinchu City (TW); Ko-Chin Chang, Hsinchu City (TW); Yu-Ming Liu, Miaoli County (TW)

(73) Assignee: UNITED MICROELECTRONICS CORP., Hsin-Chu City (TW)

(21) Appl. No.: 18/523,894

(22) Filed: Nov. 30, 2023

(30) Foreign Application Priority Data
Oct. 27, 2023 (TW) 112141329

(51) Int. Cl. H01L 29/423; H01L 29/66; H10B 41/30

(52) U.S. Cl. CPC H10D 30/6892; H10B 41/30; H10D 64/017

(57) ABSTRACT

An embedded flash memory structure, including a semiconductor substrate, an erase gate on the semiconductor substrate, two floating gates respectively at two sides of the erase gate on the semiconductor substrate, two word lines respectively at outer sides of the two floating gates, and two metal control gates respectively on the two floating gates, wherein a sacrificial layer is at at least one side of the metal control gate, and the sacrificial layer is between the metal control gate and the erase gate or between the metal control gate and the word line.

### BACKGROUND OF THE INVENTION

### 1. Field of the Invention

The present invention relates generally to an embedded flash memory structure, and more specifically, to an embedded flash memory structure with metal control gate and method of manufacturing the same.

### 2. Description of the Prior Art

Embedded Flash (eFlash) memory is a type of Flash memory that is integrated with logic device, both of them being formed on the same IC chip or die. Since interconnects aren't required in this architecture to connect different chips, performance of the device may be significantly improved, and the manufacturing cost is also reduced due to common process steps of flash memory and logic devices.

In logic process integration of eFlash memory and high-k metal gate (HKMG), since the consideration of gate height, control gate in original Flash structure is removed and source line is used to control the programming of memory instead. However, this design needs to apply higher voltage to erase gate, potentially causing the punch through of gate oxide layer and impacting the electrical property of device. Furthermore, in this design, the contact used to connect the control gate will be connected to the floating gate in lower level instead. These contacts are unable to reach the lower floating gates when they are formed and integrated in baseline HKMG process, causing short circuit issue. Accordingly, those of skilled in the art need to improve the structure and integration of current eFlash memory and HKMG process, in hope of solving the problem above.

### SUMMARY OF THE INVENTION

In the light of the aforementioned problem encountered in prior art, the present invention hereby provides a novel embedded flash memory structure and method of manufacturing the same, with feature of using logic process for high-k metal gate (HKMG) to manufacture the control gate of memory, as well as taking into account the gate height in the process integration.

One aspect of the present invention is to provide a novel embedded flash memory, with structure including a semiconductor substrate, an erase gate on the semiconductor substrate, two floating gates respectively at two sides of the erase gate on the semiconductor substrate, two word lines respectively at outer sides of the two floating gates, and two metal control gates respectively on the two floating gates, wherein a sacrificial layer is provided at at least one side of the metal control gate, and the sacrificial layer is between the metal control gate and the erase gate or between the metal control gate and the word line.

Another aspect of the present invention is to provide a method of manufacturing an embedded flash memory structure, including steps of providing a semiconductor substrate with a memory cell region and a logic device region, forming a floating gate and a sacrificial layer on the floating gate on the memory cell region of semiconductor substrate, performing a first photolithography process to form a control gate recess in the sacrificial gate, performing a first deposition process to form a polysilicon layer at two sides of the floating gate on the semiconductor substrate and in the control gate recess, performing a first planarization process to remove the polysilicon layer outside the control gate recess, thereby forming a dummy control gate in the control gate recess and an erase gate at an inner side of the floating gate, forming a dummy gate on the logic device region, forming a contact etch stop layer and an interlayer dielectric layer on the dummy control gate and the dummy gate, performing a second planarization process to remove parts of the interlayer dielectric layer and the contact etch stop layer until there is no interlayer dielectric layer on a top surface of the contact etch stop layer, performing an etching process to simultaneously remove the dummy gate and the dummy control gate, thereby forming a gate recess on the logic device region of semiconductor substrate and exposing original control gate recess on the memory cell region, and filling metal simultaneously in the gate recess and the control gate recess to form metal gate and metal control gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 13 are schematic cross-sections illustrating a process flow of manufacturing an embedded flash memory structure in accordance with the preferred embodiment of present invention;

FIG. 14 to FIG. 16 are schematic cross-sections illustrating a process flow of manufacturing an embedded flash memory structure in accordance with another embodiment of present invention; and

FIG. 17 is a schematic cross-section of an embedded flash memory structure in accordance with the preferred embodiment of present invention.

Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

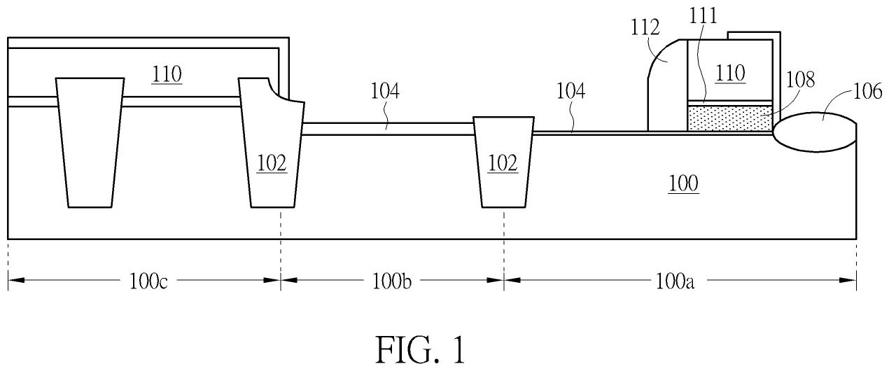

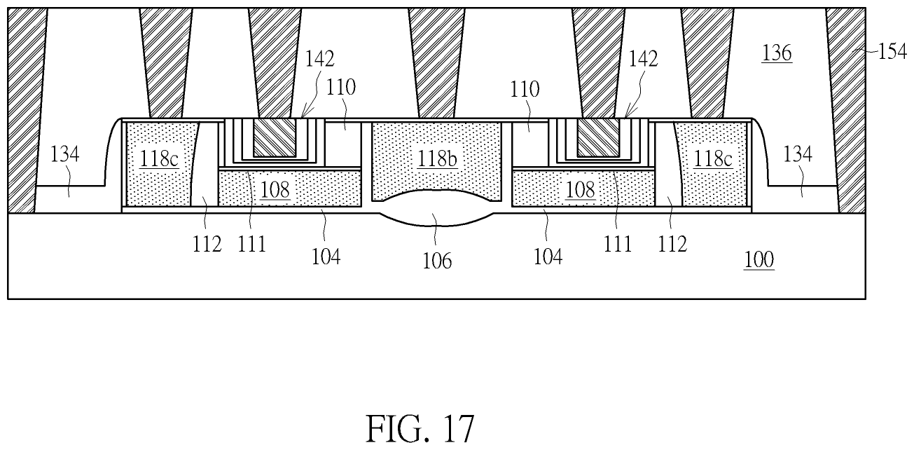

FIG. 1 to FIG. 13 will now be referred hereinafter to describe a process flow of manufacturing an embedded flash memory (eFlash) structure in accordance with the preferred embodiment of present invention, wherein relative positions and connections in vertical direction between involved components in the process are illustrated in the figures in the manner of cross-sections. The method of present invention is generally applied in the manufacture of eFlash memory and high-k metal gate (HKMG) integrated in logic process, but not limited thereto. Please note that only half of the memory structure is illustrated in the drawing for the conciseness. Complete memory structure will be elaborated in last FIG. 17.

First, please refer to FIG. 1. In the beginning of process, a semiconductor substrate 100 is provided as a basis for setting the semiconductor device of present invention. The material of substrate 100 is preferably silicon substrate, ex. a p-type doped silicon substrate, but other Si-based substrate may also be adopted, including but not limited to II-V compound semiconductor on silicon substrate (ex. GaN-on-silicon), silicon-on-insulator (SOI) substrate or substrate with other doping types. The substrate 100 may include a memory cell region 100a, a high-voltage (HV) device region 100b and a logic device region 100c, which are respectively for setting devices like memory, HV devices, core devices and input/output (I/O) devices with various functions. In the embodiment of present invention, the height of substrate in logic device region 100c, ex. fin structure, may be higher than the height of substrate in memory cell region 100a and HV device region 100b. Shallow trench isolations (STIs) 102 are formed in the semiconductor substrate 100, with material like silicon oxide to divide and isolate different active areas. Gate oxide layer 104 is formed on the semiconductor substrate 100 to serve as an insulating layer between gate and semiconductor substrate 100, wherein the thickness of gate oxide layer 104 on HV device region 100b is larger than the thickness of gate oxide layer 104 on memory cell region 100a. A field oxide layer 106 may be further formed on memory cell region 100a as an insulating layer for erase gate and source line later.

Refer still to FIG. 1. In the embodiment of present invention, a floating gate 108 is formed in advance on the memory cell region 100a at two sides of the field oxide layer 106 (only half of the structure at one side is shown in the figure) with the gate oxide layer 104 isolating it from the semiconductor substrate 100. The material of floating gate 108 may be polysilicon, with a sacrificial layer 110 further provided thereon as a layer structure for forming dummy control gate later. An inter-gate dielectric layer 111, ex. silicon nitride layer, is isolated between sacrificial layer 110 and floating gate 108. The material of sacrificial layer 110 and inter-gate dielectric layer 111 has etching selectivity, ex silicon nitride, with its pattern similar to the floating gate 108 in a direction vertical to the substrate. A spacer 112 is further formed at outer side of the floating gate 108 and sacrificial layer 110 to function as an isolating structure between floating gate 108, sacrificial layer 110 and word line. In the embodiment of present invention, sacrificial layer 110 is also formed on logic device region 100c, however, not formed on the HV device region 100b, so as to form different layer structures on logic device region 100c and HV device region 100b in later process.

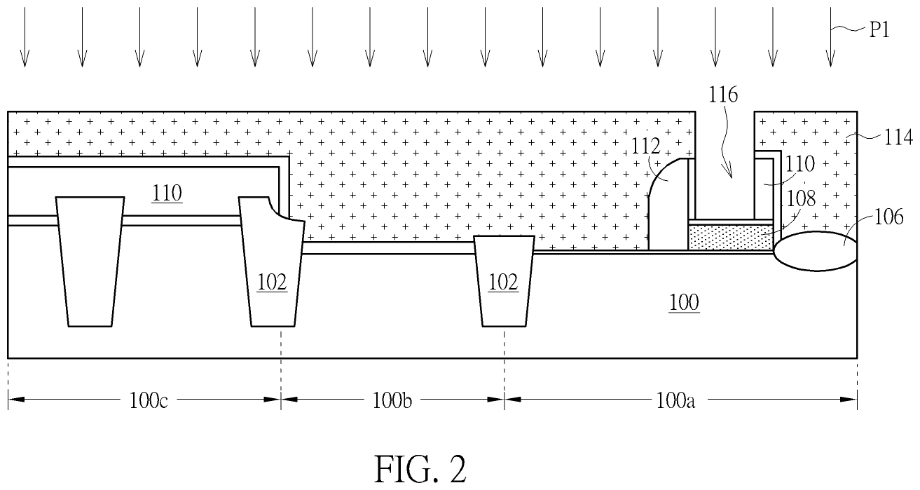

Please refer to FIG. 2. After the aforementioned structures are prepared, a photolithography process P1 is then performed to form a predetermined control gate recess 116 in the sacrificial layer 110 on memory cell region 100a. Specific steps of photolithography process P1 include first forming a photoresist 114 on entire semiconductor substrate 100 and defining the control gate pattern through steps like exposure and development. An etching process is performed thereafter using photoresist 114 as a mask to remove the sacrificial layer 110 exposed from the recess pattern, until the inter-gate dielectric layer 111 below is exposed, thereby forming the control gate recess 116. This control gate recess 116 may be used as a space for accommodating dummy control gate in later process. Please note that in the embodiment of present invention, since control gate recess 116 is formed through photolithography process rather than self-alignment process, the sacrificial layer 110 will remain at at least one side of the control gate recess 116, and control gate recesses 116 at two sides of erase gate 118b may not be symmetric with respect to the erase gate 118b.

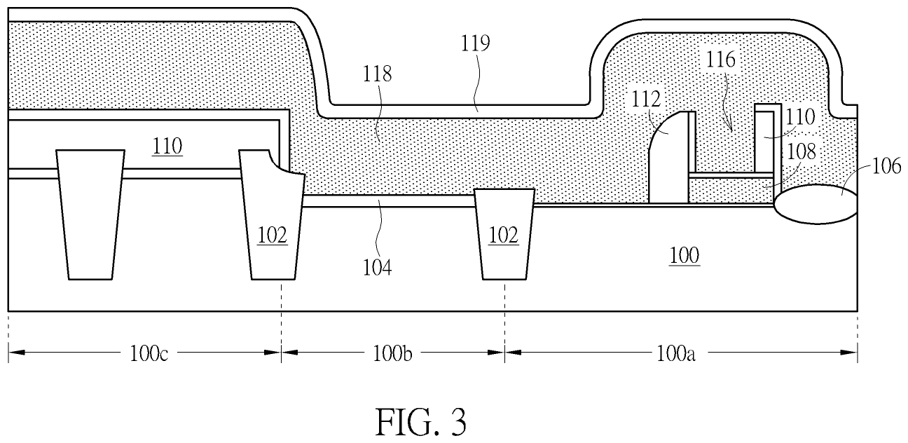

Please refer to FIG. 3. After control gate recess 116 is formed, a deposition process is then performed to form a polysilicon layer 118 and an oxide layer 119 sequentially on the semiconductor substrate 100. The polysilicon layer 118 may be formed through process like low pressure chemical vapor deposition (LPCVD) or CVD, and oxide layer 119 may be formed through CVD process. As shown in the figure, the polysilicon layer 118 covers the sacrificial layer 110 on logic device region 100c, the gate oxide layer 104 on HV device region 100b and the field oxide layer 106, sacrificial layer 110 and spacer 112 on memory cell region 100a, and its thickness in vertical direction should be large enough to fill up the control gate recess 116. Thin oxide layer 119 may be formed conformally on the polysilicon layer 118. Furthermore, since sacrificial structures are more protruding on the logic device region 100c and memory cell region 100a, the polysilicon layer 118 and oxide layer 119 formed on these two regions are also higher than their parts on HV device region 100b. The space on HV device region 100b is filled up by the polysilicon layer 118 since there is no sacrificial layer 110.

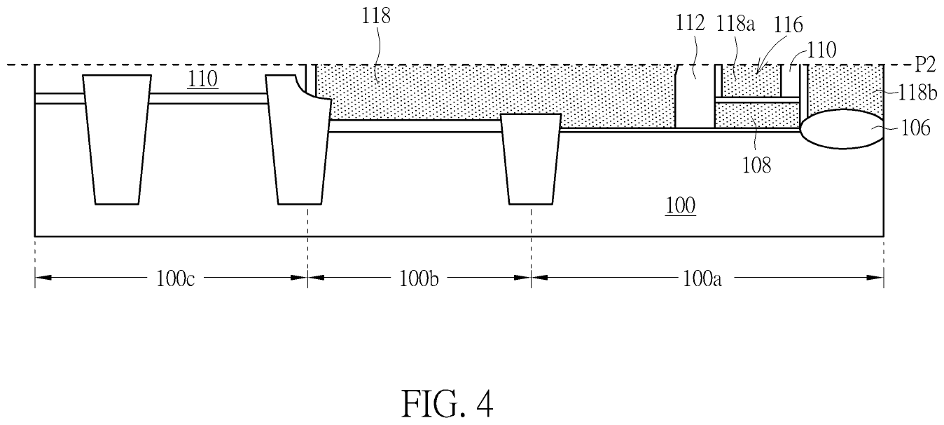

Please refer to FIG. 4. After polysilicon layer 118 and oxide layer 119 are formed, a chemical mechanical planarization (CMP) process P2 is then performed to planarize the surface of semiconductor substrate 100. As shown in the figure, the CMP process P2 will remove parts of structures like oxide layer 119, polysilicon layer 118 and spacer 112 above a predetermined level. In this way, polysilicon layer 118 on logic device region 100c is completely removed and parts of sacrificial layer 110 on logic device region 100c is removed, polysilicon layer 118 fills up the space on HV device region 100b, while polysilicon layer 118 on memory cell region 100a forms a dummy control gate 118a in the control gate recess 116 and an erase gate 118b on the field oxide layer 106. After CMP process P2, top surfaces of the layer structures on logic device region 100c, HV device region 100b and memory cell region 100a are flush. In the embodiment of present invention, an etching process may be performed in advance to remove the oxide layer 119 not on the HV device region 100b before the CMP process P2 is performed, and an etch back process may be performed after CMP process P2 to adjust the height of the aforementioned flush surface.

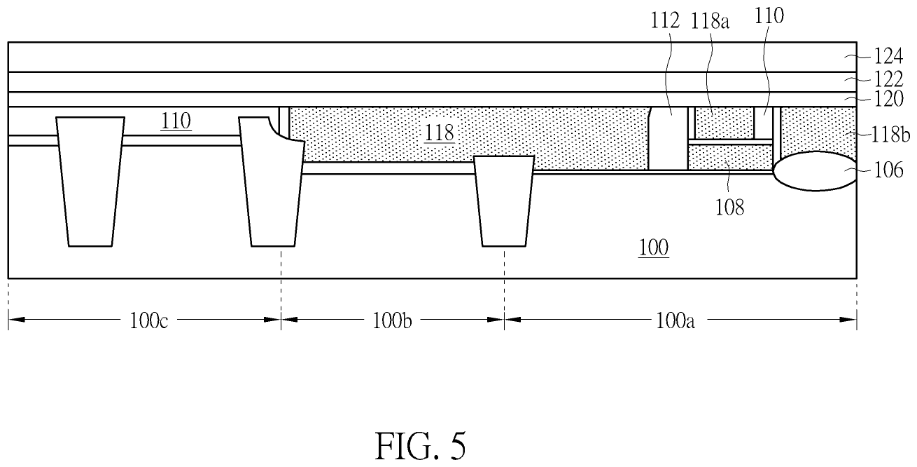

Please refer to FIG. 5. After CMP process P2, a capping layer 120, a silicon nitride layer 122 and a silicon oxide layer 124 are then formed sequentially on the flush surface, wherein the capping layer 120 may be used for the purpose of covering specific regions in later process through different substrate heights in different regions, while silicon nitride layer 122 and silicon oxide layer 124 serve as an anti-reflective structure in the photolithography process later. The capping layer 120, silicon nitride layer 122 and silicon oxide layer 124 may also function as a hard mask structure to protect HV device region 100b and memory cell region 100a in the photolithography process later. The layer structures above may all be formed through CVD process.

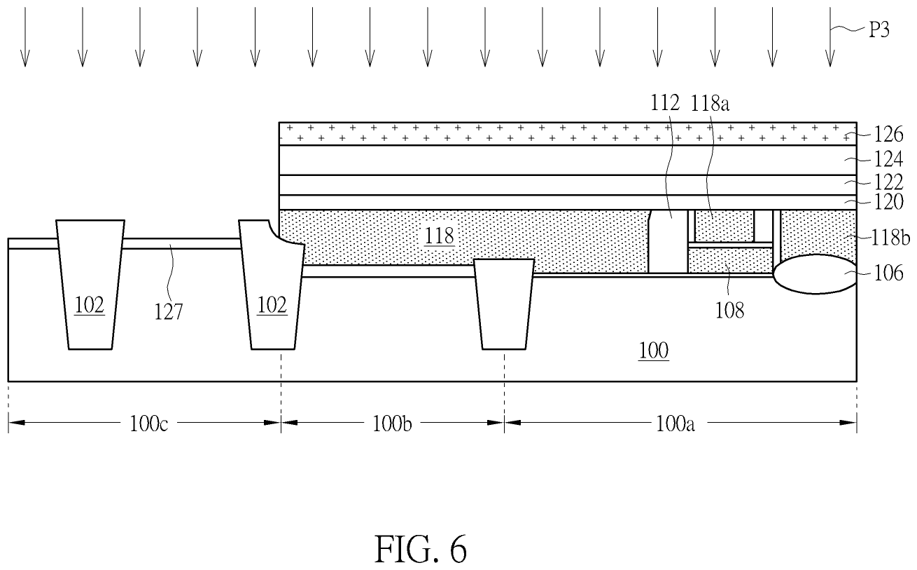

Please refer to FIG. 6. After the capping layer 120, silicon nitride layer 122 and silicon oxide layer 124 are formed, a photolithography process P3 is then performed to remove the sacrificial layer 110, capping layer 120, silicon nitride layer 122 and silicon oxide layer 124 on the logic device region 100c. Specific steps of photolithography process P3 include first forming a photoresist 126 on entire silicon oxide layer 124 and exposing entire logic device region through steps like exposure and development. An etching process is performed thereafter using photoresist 126 as a mask to remove the silicon oxide layer 124, silicon nitride layer 122, capping layer 120 and sacrificial layer 110 from the logic device region, until the oxide layer 127 and STIs 102 below are exposed. In this way, it may begin to manufacture logic devices on the logic device region 100c.

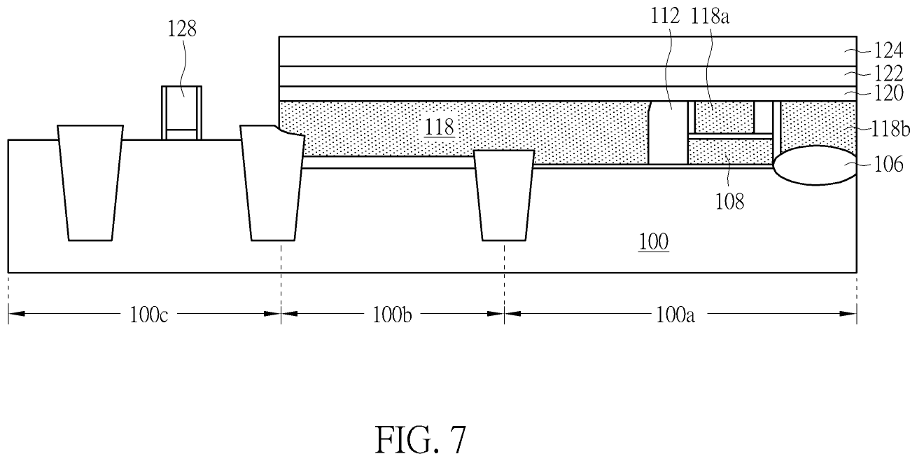

Please refer to FIG. 7. After the aforementioned layer structures on logic device region 100c are removed, a dummy gate 128 is then formed on the logic device region 100c. Steps of forming dummy gate 128 may include removing the oxide layer 127 on the logic device region 100c, forming a gate oxide layer and a polysilicon layer on the logic device region 100c, patterning the polysilicon layer to form a dummy gate 128, forming spacers at two sides of the dummy gate 128, and forming structure like lightly-doped drains (LDD) in the semiconductor substrate 100 of logic device region 100c. Since components and relevant process of logic device above are conventional skill and not the key point of present invention, relevant detailed description will be herein omitted, and a number 128 is used in the figure to denote entire dummy gate.

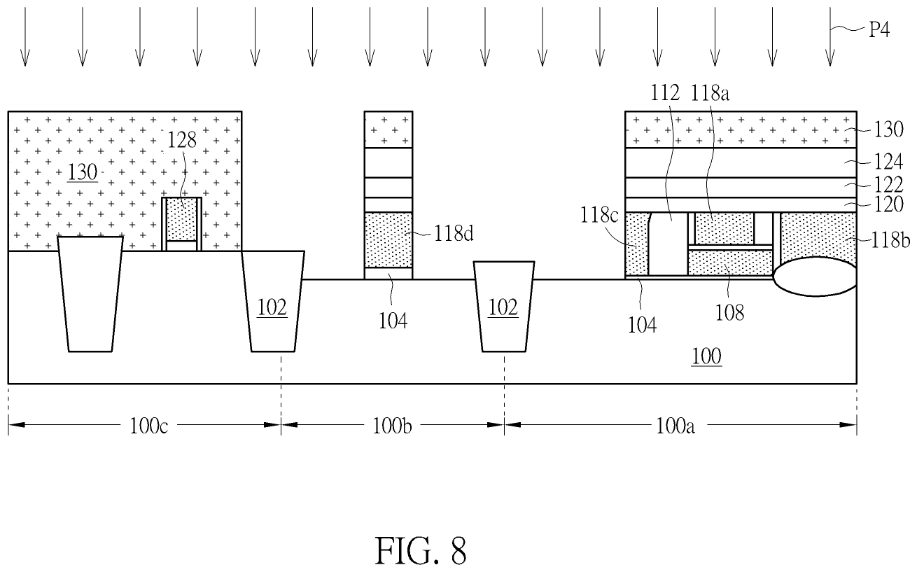

Please refer to FIG. 8. After dummy gate 128 is formed, a photolithography process P4 is then performed to pattern the layer structure on HV device region 100b like polysilicon layer 118, capping layer 120, silicon nitride layer 122 and silicon oxide layer 124, thereby forming gate 118d for HV device on the HV device region 100b. Please note that in the embodiment of present invention, photolithography process P4 simultaneously pattern the polysilicon layer 118 on the memory cell region 100a, so as to form word line 118c for eFlash structure. Specific steps of photolithography process P4 include first forming a photoresist 130 on entire semiconductor substrate 100. The photoresist 130 substantially covers entire logic device region 100c and gate pattern are formed on the HV region 100b through exposure and development steps. The photoresist 130 also covers the portions like erase gate 118b, floating gate 108, spacer 112 and predetermined word line 118c on the memory cell region 100a. Thereafter, an etching process is performed using photoresist 130 as a mask to remove the silicon oxide layer 124, silicon nitride layer 122, capping layer 120, polysilicon layer 118 and gate oxide layer 104 exposed from the photoresist 130, until the semiconductor substrate 100 and STIs 102 below are exposed, thereby forming the gate 118d on HV device region 100b and the word line 118c on memory cell region 100a. It can be known from the embodiment above that the gate 118d on HV device region 100b, the word line 118c, dummy control gate 118a and erase gate 118b on memory cell region 100a are all formed from the original polysilicon layer 118.

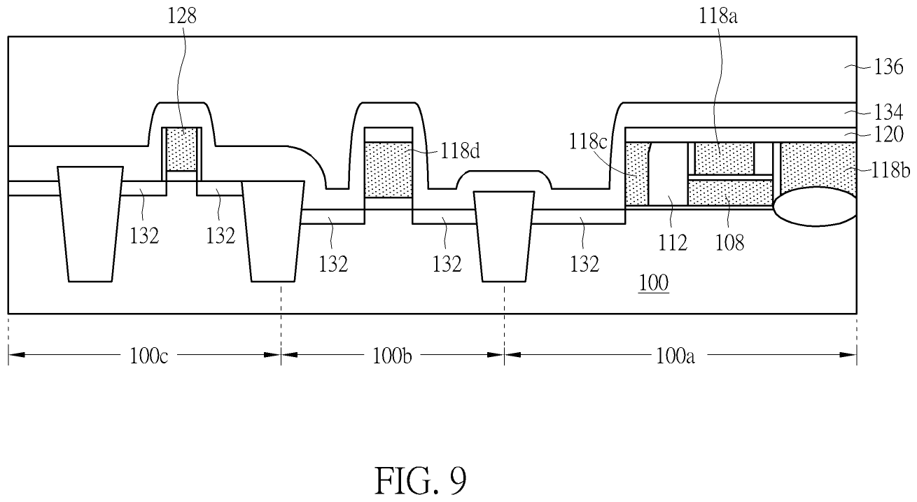

Please refer to FIG. 9. After gate 118d and word line 118c are formed, photoresist 130 is removed and ion implantation process is then performed to dope source/drain 132 in semiconductor substrate 100. Source/drain 132 are formed in the semiconductor substrate 100 at two sides of dummy gate 128, at two sides of gate 118d, and at outer side of word line 118c. In certain embodiment, silicon structure may be formed first in germanium (SiGe) epitaxial semiconductor substrate 100 and then be doped to form source/drain 132. Thereafter, anti-reflective layer structure like silicon nitride layer 122 and silicon oxide layer 124 are removed, and a contact etch stop layer (CESL) 134 and an interlayer dielectric (ILD) of layer 136 are then formed sequentially on the surface semiconductor substrate 100 through deposition process. The material of CESL 134 may be silicon nitride, which may be formed conformally on the substrate surface through CVD or other suitable process. CESL 134 not only functions as an etch stop layer, but also provides the effect of locally strained Si for those contacting devices. The material of ILD layer 136 may be porous silicon oxide, which may be formed through deposition process with good fillability, ex. high aspect ratio process (HARP), HDP-CVD or spin coating. Please note that in this stage, capping layer 120 only remains on HV device region 100b and memory cell region 100a. Capping layer 120 on the logic device region 100c has been removed in the photolithography process P3 of FIG. 6. However, since the semiconductor substrate 100 in logic device region 100c is higher, the levels of top surface of CESL 134 deposited on the three regions are substantially the same.

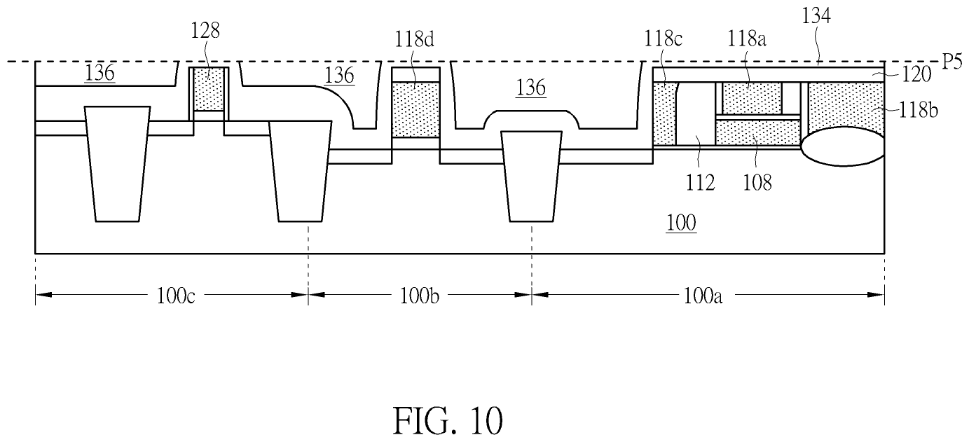

Please refer to FIG. 10. After CESL 134 and ILD layer 136 are formed, a CMP process P5 is then performed to planarize the surface of semiconductor substrate 100. As shown in the figure, the CMP process P5 will remove the parts of ILD layer 136 and CESL 134 above a predetermined level. In this way, ILD layer 136 on dummy gate 128, gate 118d and flash memory structure are all removed, and other remaining ILD layer 136 is filled in the spaces between dummy gate 128, gate 118d and flash memory structure. After CMP process P5, CESL 134 on the dummy gate 128, gate 118d and flash memory structure will be flush with surrounding ILD layer 136.

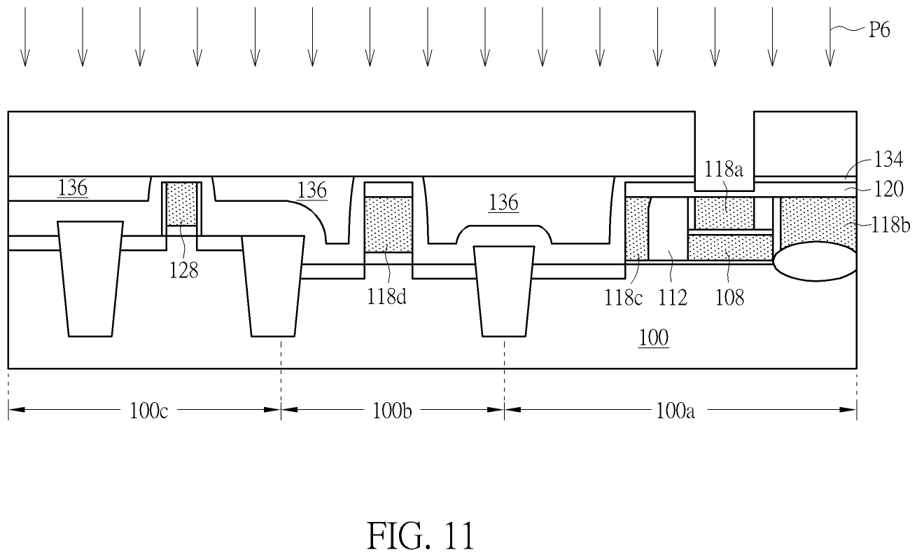

Please refer to FIG. 11. After CMP process P5, a photolithography process P6 is then performed to remove the CESL 134 and parts of the capping layer 120 above the dummy control gate 118a on memory cell region 100a. The purpose of this step is to make the thickness of layer structures on the dummy gate 128 of logic device region 100c and dummy control gate 118a of memory cell region 100a the same. For example, only a CESL 134 remains on the dummy gate 128 and only a thin capping layer 120 remains on dummy control gate 118a, so that the dummy gate 128 and dummy control gate 118a on these two regions may be removed simultaneously in the process of removing dummy gate later.

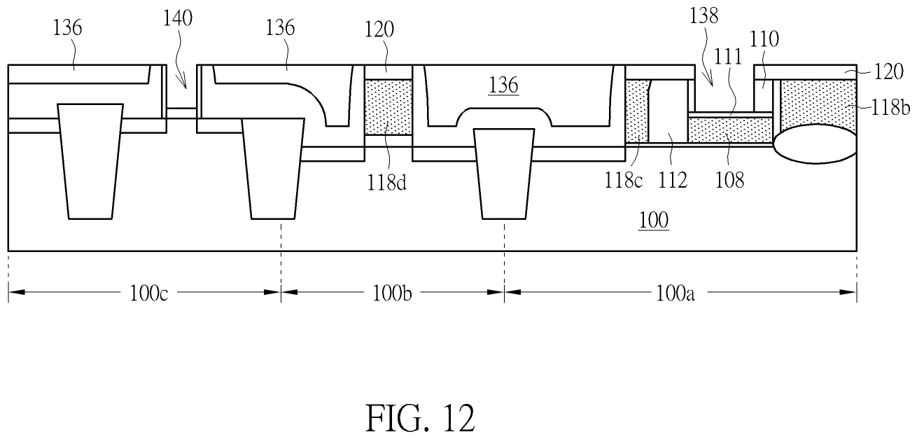

Please refer to FIG. 12, After photolithography process P6, the photoresist is removed, and a removing process is then performed to simultaneously remove the dummy gate 128 on logic device region 100c and dummy control gate 118a on memory cell region 100a. This removing process may be dry etching process, wet etching process, etch back process, one or more other available process directed to polysilicon material, for example the wet etching process adopting ammonia as an etchant. Layer structures like CESL 134 and capping layer 120 once remaining on the dummy gate 128 and dummy control gate 118a may also be removed in this process. Since gate 118d on HV device region 100b is covered by CESL 13 and thick capping layer 120, it may not be affected by the aforementioned process. After the dummy gate 128 and dummy control gate 118a are removed, gate recess 140 and control gate recess 138 are formed respectively on their original positions, which may be used to accommodate metal gate and metal control gate to be formed later respectively.

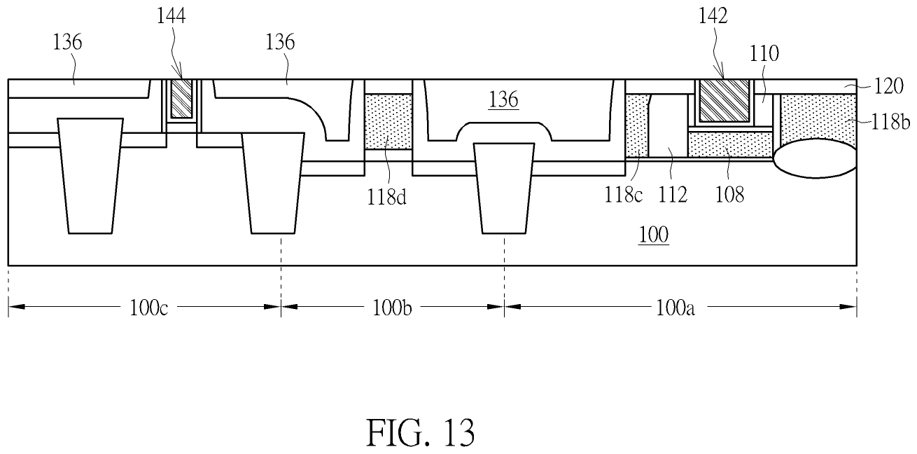

Please refer to FIG. 13. After gate recess 140 and control gate recess 138 are formed, a replacement metal gate (RMG) process is then performed to form metal gate g 144 and metal control gate 142 respectively in the gate recess 140 and control gate recess 138. Specific steps of this RMG process may include forming a high-k dielectric layer first in the recess, with material including but not limited to HfO_{X}, HfSiO_{X}, HESiON, ZrO₂, HfZrO_{X}, AlO_{X} or TiO_{X}. Metal layers like work function metal (chosen from suitable metal material depending on required work function property), barrier metal (ex. Ti, Ta), low-resistance metal (ex. Al) are then formed in the recess. The aforementioned various metal components may be multilayered metal, which may be distributed conformally along the U-shaped recess surface, or fill up the whole recess, or the combination thereof. Besides, the present invention is not limited to high-k last process. In other embodiment, for example in high-k first process, the high-k dielectric layer may be formed in advance before the aforementioned step of forming dummy gate 128 in FIG. 7, so that the high-k dielectric layer would be provided only on logic device region 100c.

Since the presence of capping layer 120, top surface of the metal control gate 142 formed on memory cell region 100a may be higher than the surrounding sacrificial layer 110 and flush with the capping layer 120. Since detailed structure and relevant process of the metal gate device is conventional skill. Relevant detailed description will be herein omitted, and numbers 142 and 144 are used in the figure to denote the metal control gate and metal gate respectively that consist of the aforementioned components.

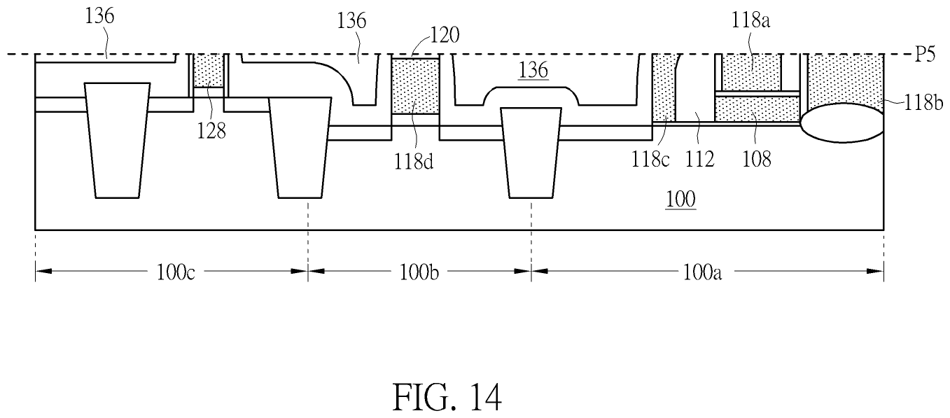

FIG. 14 to FIG. 16 will now be referred hereinafter to describe a process flow of manufacturing an eFlash structure in accordance with another embodiment of present invention, which is difference from the aforementioned embodiment in the process that the word line and erase gate of eFlash structure are integrally manufactured through the HKMG process.

First, please refer to FIG. 14. The preprocess of this embodiment is similar to the steps prior to FIG. 10, which the steps progress to finish of CMP process P5. Different from the previous embodiment, the predetermined grinding level in the CMP process P5 of this embodiment is lower than the flush level of the embodiment of FIG. 10, so that the CESL 134 on dummy gate 128, gate 118d and Flash structure will all be completely removed, and even higher parts of the dummy gate 128 are removed. In addition, with respect to this embodiment, the height of gate 118d on HV device region 100b is not leveled with the simultaneously formed word line 118c on memory cell region 100a. Instead, it is designedly lower than the word line 118c, so that parts of the capping layer 120 will remain on gate 119d after CMP process P5, to function as a blocking layer in the step of removing polysilicon layer later, avoiding the removal of gate 118d on HV device region 100b.

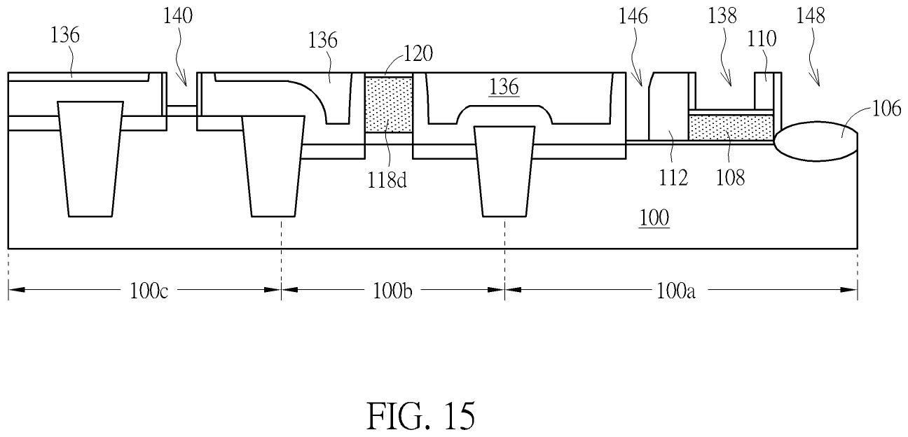

Please refer to FIG. 15. After CMP process P5, a removing process is then performed directly to remove exposed polysilicon-based layer on every region, including the dummy gate 128 on logic device region 100c and the word line 118c, dummy control gate 118a and erase gate 118b on memory cell region 100a. Since previous CMP process P5 is performed to the degree that the dummy gate 128 and dummy control gate 118a are exposed, thus photolithography process P6 like the one in FIG. 11 is not required in this embodiment to adjust the thickness of capping layer 120. The gate 118d on HV device region 100b is not affected by the removing process since it is covered by the remaining capping layer 120. In this way, after dummy gate 128, word line 118c, dummy control gate 118a and erase gate 118b are removed, gate recess 140, word line recess 146, control gate recess 138 and erase recess 148 will be formed respectively on their original positions, which may accommodate the structures like metal gate, metal word line, metal control gate and metal erase gate to be formed later.

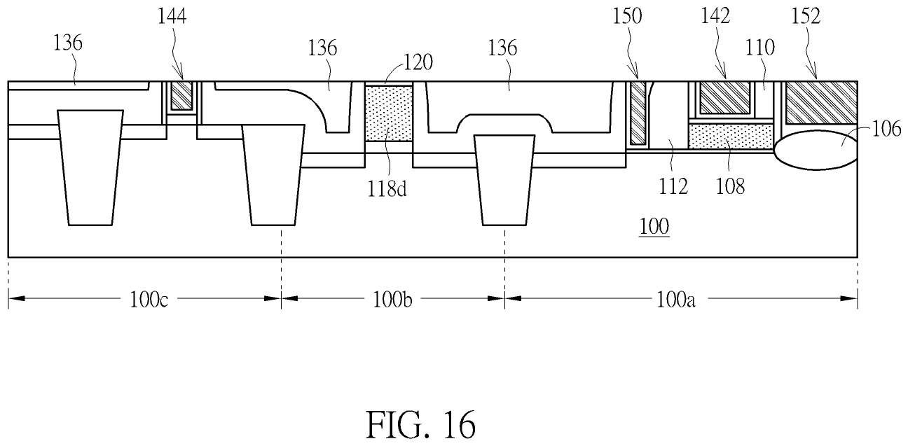

Please refer to FIG. 16. After gate recess 140, word line recess 146, control gate recess 138 and erase gate recess 148 are formed, similar to the embodiment of FIG. 13, a RMG process is then performed to formed and integrated the structures like metal gate 144, metal word line 150, metal control gate 142 and metal erase gate 152 respectively in gate recess 140, word line recess 146, control gate recess 138 and erase recess 148. The metal structures above may all include the aforementioned metal components like high-k dielectric layer, work function metal layer, barrier metal, low-resistance metal, etc., with their top surface all flush with remaining sacrificial layer 110 on the memory cell region 100a. The aforementioned various metal layers may be multilayered metal, which may be distributed conformally along the U-shaped recess surface, or fills up the whole recess, or the combination thereof. Besides, the present invention is not limited to high-k last process. In other embodiment, for example in high-k first process, the high-k dielectric layer may be formed in advance before the step of forming dummy gate 128 in FIG. 7, so that the high-k dielectric layer will only be provided on logic device region 100c. Since components and relevant process of the metal gate above are conventional skill and not the key point of present invention, relevant detailed description will be herein omitted, and numbers 144, 150, 142 and 152 are used in the figure to denote the metal structures including the aforementioned components.

Please refer now to FIG. 17, which is a schematic cross-section of an eFlash structure in accordance with the preferred embodiment of present invention. According to the process shown in the aforementioned embodiments, the present invention further provides a novel eFlash structure. As shown in the figure, the structure includes a semiconductor substrate 100, an erase gate 118b on the semiconductor substrate 100, and a field oxide layer further provided between the erase gate 118b and semiconductor substrate 100. Two floating gates 108 is at two sides of erase gate 118b respectively on the semiconductor substrate 100, and a gate oxide layer 104 is provided between the floating gate 108 and semiconductor substrate 100. Two word lines 118c is at outer sides of two floating gates 108 respectively, with a gate oxide layer 104 between the word line 118c and semiconductor substrate 100 and a spacer 112 between the word line 118 and floating gate 108. Two metal control gates 142 are on the two floating gates 108 respectively, wherein a sacrificial layer 110 is provided at at least one side of the metal control gate 142. The sacrificial layer 110 is between the metal control gate 142 and erase gate 118b or between the metal control gate 142 and word line 118c. The two metal control gates 142 may not be symmetric with respect to the erase gate 118b. An inter-gate dielectric layer 111 is provided between the sacrificial layer 110, metal control gate 142 and the floating gate 108. In addition, a CESL 134 may be further provided at outer sides of two word lines 118c. The CESL 134 and entire eFlash structure may be covered with an ILD layer 136. Contacts 154 may be provided in the ILD layer 136 that connect with the components like erase gate 118b, metal control gate 142, word line 118c of the eFlash: structure, in order to connect these components to back-end-of-line (BEOL) circuit.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An embedded flash memory structure, comprising:
a semiconductor substrate;
an erase gate on said semiconductor substrate;
two floating gates respectively at two sides of said erase gate on said semiconductor substrate;
two word lines respectively at outer sides of said two floating gates; and
two metal control gates respectively on said two floating gates, wherein a sacrificial layer is provided at at least one side of said metal control gate, and said sacrificial layer is between said metal control gate and said erase gate or between said metal control gate and said word line.

2. The embedded flash memory structure of claim 1, wherein a material of said sacrificial layer is silicon nitride.

3. The embedded flash memory structure of claim 1, wherein a top surface of said metal control gate is higher than a top surface of said sacrificial layer.

4. The embedded flash memory structure of claim 1, wherein said word line is metal word line, said erase gate is metal erase gate, and tops surface of said metal word line, said metal erase gate and said metal control gate are flush.

5. The embedded flash memory structure of claim 1, wherein said semiconductor substrate is provided with a memory cell region and a logic device region, said metal control gate is on said memory cell region, and a top surface of said metal control gate is flush with a top surface of a metal gate on said logic device region.

6. The embedded flash memory structure of claim 5, wherein said semiconductor substrate is further provided with a high-voltage device region, a polysilicon gate is provided on said high-voltage device region, a top surface of said polysilicon gate is flush with a top surface of said erase gate and a top surface of said word line on said memory cell region, but lower than said top surface of said metal gate on said logic device region and said top surface of said metal control gate.

7. The embedded flash memory structure of claim 1, wherein said two metal control gates are not symmetric with respect to said erase gate.

8. A method of manufacturing an embedded flash memory structure, comprising:
providing a semiconductor substrate with a memory cell region and a logic device region;
forming a floating gate and a sacrificial layer on said floating gate on said memory cell region of said semiconductor substrate;
performing a first photolithography process to form a control gate recess in said sacrificial gate;
performing a first deposition process to form a polysilicon layer at two sides of said floating gate on said semiconductor substrate and in said control gate recess;
performing a first planarization process to remove said polysilicon layer outside said control gate recess, thereby forming a dummy control gate in said control gate recess and an erase gate at an inner side of said floating gate;
forming a dummy gate on said logic device region;
forming a contact etch stop layer and an interlayer dielectric layer on said dummy control gate and said dummy gate;
performing a second planarization process to remove parts of said interlayer dielectric layer and said contact etch stop layer until there is no said interlayer dielectric layer on a top surface of said contact etch stop layer;
performing an etching process to simultaneously remove said dummy gate and said dummy control gate, thereby forming a gate recess on said logic device region of said semiconductor substrate and exposing original said control gate recess on said memory cell region; and
filling metal simultaneously in said gate recess and said control gate recess to form metal gate and metal control gate.

9. The method of manufacturing an embedded flash memory structure of claim 8, wherein said second planarization process doesn't expose said dummy control gate, and a capping layer is further provided between said dummy control gate and said contact etch stop layer, and further comprising performing a second photolithography process to remove said contact etch stop layer and parts of said capping layer on said dummy control gate after said second planarization process.

10. The method of manufacturing an embedded flash memory structure of claim 8, further comprising performing a third photolithography process to pattern said polysilicon layer after said dummy gate is formed, thereby forming a word line at an outer side of said floating gate.

11. The method of manufacturing an embedded flash memory structure of claim 10, wherein said semiconductor substrate is further provided with a high-voltage device region, and said step of performing a third photolithography process to pattern said polysilicon layer simultaneously forms said word line on said memory cell region and gates on said high-voltage device region.

12. The method of manufacturing an embedded flash memory structure of claim 11, wherein said second planarization process exposes said dummy gate, said dummy control gate, said word line and said erase gate, and said etching process simultaneously removes said dummy gate, said dummy control gate, said word line and said erase gate, thereby forming said gate recess on said logic device region of said semiconductor substrate, forming word line recess and erase gate recess on said memory cell region of said semiconductor substrate and exposing original said control gate recess on said memory cell region.

13. The method of manufacturing an embedded flash memory structure of claim 12, further comprising filling metal simultaneously in said gate recess, said word line recess, said control gate recess and said erase gate recess, thereby forming said metal gate, said metal control gate, metal word line and metal erase gate.
